(19) United States
(12) Patent Application Publication
(10) Pub. No.: US 2011/0256336 A1
(43) Pub. Date: Oct. 20, 2011

(54) COMPOSITE CARBON AND MANUFACTURING METHOD THEREFOR

(75) Inventor: Yosuke Koike, Aichi (JP)

(73) Assignees: TOYOTA JIDOSHA KABUSHIKI KAISHA, Toyota-shi, Aichi (JP); AISIN SEIKI KABUSHIKI KAISHA, Kariya-shi, Aichi (JP)

(21) Appl. No.: 13/141,015

(22) PCT Filed: Dec. 18, 2009
(86) PCT No.: PCT/JP2009/071730

§ 371 Date: Jun. 20, 2011

(30) Foreign Application Priority Data
Dec. 22, 2008 (JP) 2008-324953

(51) Int. Cl. C23C 16/26; B32B 33/00; B82Y 30/00; B82Y 40/00

(52) U.S. Cl. 428/95; 427/249.4; 977/843; 977/961

(57) ABSTRACT

Disclosed is a composite carbon having a novel structure. This composite carbon has fibrous carbon which extends in the direction of the long axis, and multiple carbon nanotubes which are formed on the surface of the fibrous carbon and have a smaller diameter than the diameter of the fibrous carbon. The carbon nanotubes are formed as a group of multiple carbon nanotubes, with the lengthwise directions of each of the carbon nanotubes aligned in the same direction.

### TECHNICAL FIELD

The present invention relates to a composite carbon having a structure in which relatively extremely fine multiple carbon nanotubes are formed on the surface of a fibrous carbon, and a manufacturing method therefor.

### BACKGROUND ART

A composite carbon in which relatively extremely fine multiple carbon nanotubes are randomly formed on the surface of a fibrous carbon is disclosed in Patent Documents 1 and 2. Patent Document 1 discloses a method of forming carbon nanotubes on the entire surface of a fibrous carbon forming carbon paper. The method includes sticking an iron catalyst on the surface of the carbon paper, immersing the carbon paper in methanol while both ends thereof are pinched to connect metal electrodes, and supplying DC current between the electrodes to heat the carbon paper to 800° C., thereby forming the carbon nanotubes. In the carbon nanotube disclosed in the Patent Documents, the lengthwise direction thereof is not aligned in the same direction as the long axis direction of the fibrous carbon.

### Cited Reference

Patent document

Patent Document 1: Japanese Unexamined Patent Publication No. 2005-213700

Patent Document 2: Japanese Unexamined Patent Publication No. 2007-194354

### SUMMARY OF INVENTION

Accordingly, the present invention has been made keeping in mind the above problems occurring in the related art, and is intended to provide a composite carbon having a novel structure in which multiple carbon nanotubes, each having the extremely fine size, are formed on the surface of a fibrous carbon while having directionality, and a method of manufacturing the same.

The composite carbon includes: a fibrous carbon extending in a direction of a long axis thereof; and multiple carbon nanotubes formed on the fibrous carbon and having a smaller diameter than a diameter of the fibrous carbon, wherein the carbon nanotubes are formed as a group of multiple carbon nanotubes with the lengthwise direction thereof aligned in the same direction.

The method of manufacturing the composite carbon includes: preparing a fibrous carbon extending in a direction of a long axis thereof and having an aluminum substrate thereon and an iron catalyst stuck on the aluminum substrate; and forming, on the surface of the fibrous carbon, multiple carbon nanotubes having a smaller diameter than a diameter of the fibrous carbon, as a group of carbon nanotubes with the lengthwise directions thereof aligned in the same direction, by CVD-processing a carbon source by means of a CVD apparatus.

According to the composite carbon of the present invention, multiple carbon nanotubes are formed on the surface of the fibrous carbon such that the lengthwise directions thereof are aligned in a direction perpendicular to the long axis of the fibrous carbon. Because of this, a composite carbon having a novel structure can be accomplished which is advantageous in increasing a specific surface area than the fibrous carbon. Further, a composite carbon having a novel structure can be accomplished which is advantageous in improving an aspect ratio (long axis/short axis) of the carbon nanotube because the carbon nanotube can be grown at some length.

Such a composite carbon contributes to increased specific surface area, improved porosity, reduced electric resistance, and improved conductivity. Further, provided that a catalyst is loaded in the composite carbon, it can be estimated that utilization of the catalyst will increase. Such a composite carbon is adaptable to carbon material used for fuel cells, capacitors, carbon material used for an electrode or the like of lithium cells, secondary cells, liquid junction solar cells, or the like, an electrode of industrial appliance, or the like.

### BRIEF DESCRIPTION OF DRAWINGS

FIG. 1 is a schematic view showing the concept of a composite carbon according to a first embodiment.

FIG. 2 is a schematic view showing the concept of the composite carbon of the first embodiment as seen in a different direction.

FIG. 3 is a microscopic (SEM) photograph showing the composite carbon of the first embodiment.

FIG. 4 is a microscopic (SEM) photograph showing the composite carbon of the first embodiment.

FIG. 5 is an enlarged microscopic (SEM) photograph showing a portion near carbon nanotubes of the composite carbon of the first embodiment.

FIG. 6 is a further enlarged microscopic (SEM) photograph showing a portion near carbon nanotubes of the composite carbon of the first embodiment.

FIG. 7 is a microscopic (SEM) photograph showing a composite carbon according to a fifth embodiment.

FIG. 8 is a microscopic (SEM) photograph showing the composite carbon of the fifth embodiment.

FIG. 9 is a microscopic (SEM) photograph showing the composite carbon of the fifth embodiment.

FIG. 10 is a microscopic (SEM) photograph showing a composite carbon according to a sixth embodiment.

FIG. 11 is a microscopic (SEM) photograph showing the composite carbon of the sixth embodiment.

FIG. 12 is a microscopic (SEM) photograph showing a composite carbon according to a first reference example.

FIG. 13 is a microscopic (SEM) photograph showing the composite carbon of the first reference example.

FIG. 14 is a cross-sectional view schematically showing a fuel cell according to an application example.

FIG. 15 is a cross-sectional view schematically showing a capacitor according to an application example.

### BEST MODES FOR CARRYING OUT THE INVENTION

A composite carbon according to the present invention has a structure in which multiple carbon nanotubes are formed on the surface of single fibrous carbon. The length and diameter of the carbon nanotube is smaller than the length and diameter of the fibrous carbon. In this case, the multiple carbon nanotubes are formed on the surface of the fibrous carbon while forming a group thereof, such that the lengthwise directions thereof are aligned perpendicular to the direction of a long axis of the fibrous carbon. This contributes to an increase in a specific surface area and conductive path of the composite carbon. This also contributes to control of micro pores such as a size, distribution, or the like.

The fibrous carbon may be formed of carbon having a fibrous shape. The fibrous carbon may be formed of e.g. carbon fiber itself The fibrous carbon may be either long fiber which extends continuously, or short fiber of 30 mm or less. Further, the fibrous carbon may be formed of carbon fiber that forms fibrous carbon aggregate such as carbon paper, carbon cloth, carbon felt, or the like. Furthermore, the fibrous carbon may also be formed of carbon nanofiber. Thus, the fibrous carbon aggregate may preferably be one of the carbon paper, the carbon cloth, and the carbon felt. The carbon paper may be formed by screening a dispersion solution containing carbon fiber and cellulose-based flammable fiber (e.g. pulp) though a sieve screen for paper-drafting thereby to form fiber aggregate and burning the cellulose-based fiber, thereby forming the carbon paper. The fiber length and diameter of the fibrous carbon may be of any magnitude, provided it can contain carbon nanotubes. For example, although not limited thereto, the fiber length may be of a range of 5 nm-300 mm, particularly 1 nm-10 mm, and the fiver diameter may be of a range of 5 nm-100 μm, or 3 nm-10 μm. Further, the fiber length may have a range of 5 μm-300 mm, particularly 1 μm-10 mm, and the fiber length may have a range of 5 μm-100 μm, or 3 μm-10 μm.

Here, the carbon nanotubes forming a group may be aligned such that the lengthwise direction thereof is perpendicular to the direction of a long axis of the fibrous carbon. Alternatively, the carbon nanotubes may be aligned such that the lengthwise direction thereof is oriented at an angle θ relative to a direction perpendicular to the long axis of the fibrous carbon. For example, the angle θ may have a range of 0°-±45°, 0°-±30°, 0°-±10°, 0°-±5°, or 0°-±3°. In brief, according to the present invention, multiple carbon nanotubes forming a group are aligned such that the lengthwise direction thereof is perpendicular to the long axis of the fibrous carbon (i.e. the diametric direction of the fibrous carbon). However, the angle of θ used herein is an angle exactly after growth of the carbon nanotube, and the angle θ may often increase up to about 90° when the carbon nanotubes aggregate through post treatment (platinum immersion, electrolyte impregnation, or the like).

A carbon source to produce carbon nanotubes may be for example aliphatic hydrocarbon such as alkane, alkene, alkyne, or the like, aliphatic compound such as alcohol, ethyl, or the like, aromatic compound such as aromatic hydrocarbon or the like. Thus, a CVD method may be exemplified which uses alcoholic source gas and hydrocarbon-based source gas as a carbon source. The alcoholic source gas maybe methyl alcohol, ethyl alcohol, propanol, butanol, pentanol, hexanol, or the like. In addition, the hydrocarbon-based source gas may be methane gas, ethane gas, acetylene gas, propane gas, or the like.

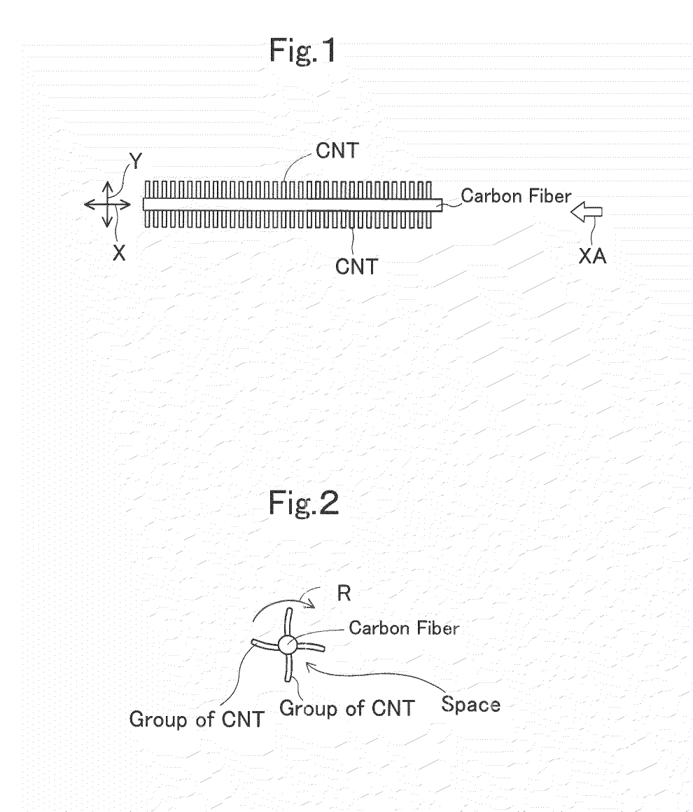

According to the composite carbon of the present invention, the carbon nanotubes were exemplified as being of a plurality of groups spaced a distance in a circumferential direction of the fibrous carbon (see FIG. 2). Here, the group of the carbon nanotubes may preferably be formed as any one of first to fourth groups in the circumferential direction of the carbon nanotubes. Further, according to the composite carbon of the present invention, the plurality of carbon nanotubes are arranged in a direction of a long axis of the fibrous carbon, forming a group of the carbon nanotubes (see FIG. 1). Here, the carbon nanotubes are aligned in the direction of the long axis of the fibrous carbon. This causes a further increase in a specific surface area of the composite carbon. The length of the carbon nanotube may preferably be smaller than that of the fibrous carbon.

The fibrous carbon may preferably be carbon fiber forming carbon fiber aggregate containing multiple carbon fibers. The carbon nanotubes may be formed by a CVD method. The carbon annotubes may preferably be formed on an iron thin film which is formed on the surface of the fibrous carbon. The iron thin film may preferably be formed on an aluminum substrate which is formed on the surface of the fibrous carbon. The thickness of the aluminum substrate has a range of 20 nm-50 nm, and the thickness of the iron thin film has a range of 18 nm-80 nm, preferably 20 nm-65 nm.

According to the manufacturing method for the composite carbon, fibrous carbon is prepared which extends in a direction of a long axis thereof while having an aluminum substrate and an iron catalyst provided on the aluminum substrate. Here, the aluminum substrate is formed on the surface of the fibrous carbon. Next, the iron catalyst is prepared on the aluminum substrate. The thickness of the aluminum substrate preferably has a range of 2-50 nm, 10-50 nm, or 20-50 nm. The thickness of the iron thin film preferably has a range of 2-80 nm, 10-80 nm, or 20-65 nm. However, these thicknesses are not limited thereto.

Next, multiple carbon nanotubes having a smaller diameter than a diameter of the fibrous carbon are formed on the surface of the fibrous carbon as a group of carbon nanotubes in which the lengthwise directions thereof are aligned in the same direction, by CVD-processing a carbon source by means of a CVD apparatus. Like this, compared to the case where the iron catalyst is prepared on the fibrous carbon, in case where the aluminum substrate is first prepared on the fibrous carbon, and then the iron catalyst is stuck on the aluminum substrate, the carbon nanotubes can be effectively formed as a group such that the lengthwise directions thereof are aligned in the same direction. Although not clear, it is supposed that forming the iron catalyst on the aluminum substrate makes the iron catalyst finer.

### First Embodiment

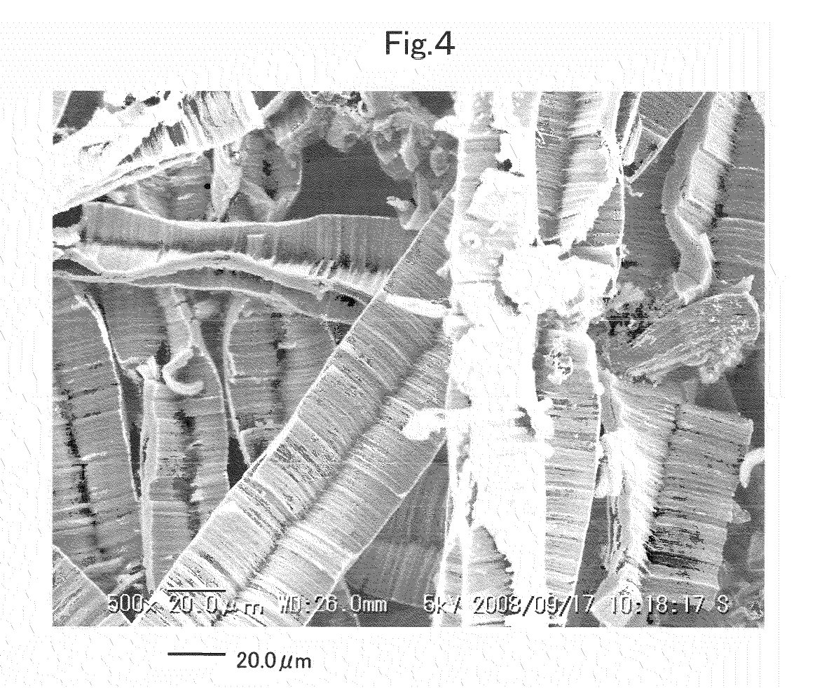

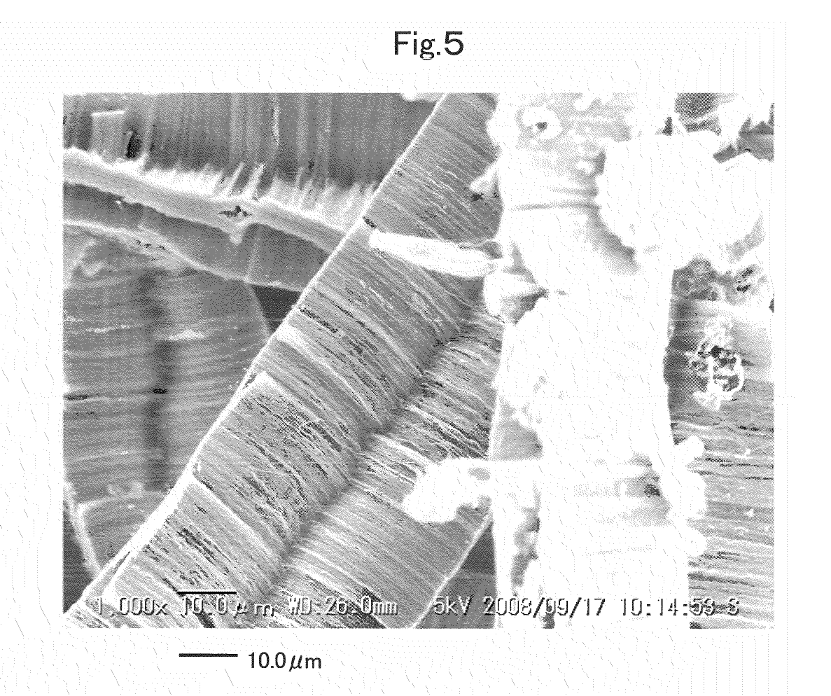

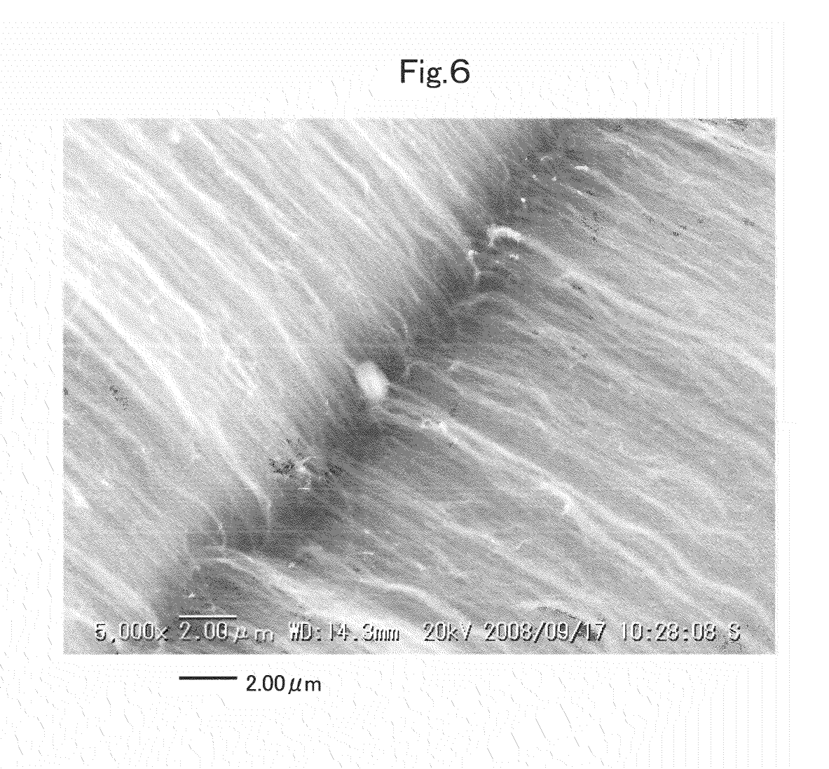

The first embodiment of the present invention will now be described with reference to FIGS. 1 to 5. The composite carbon of this embodiment has carbon fibers serving as fibrous carbon and multiple carbon nanotubes. Here, the carbon nanotubes are formed on the fibrous carbon as a group such that the lengthwise directions thereof are aligned perpendicular to the direction of the long axis of the carbon fiber. A process of manufacturing the composite carbon of the present embodiment will now be described.

(Manufacture of Carbon Paper)

First, carbon fibers serving as fibrous carbon and pulp serving as flammable fiber which is flammable by means of heat treatment were prepared. A dispersion solution in which the carbon fiber and the pulp (cellulose-based flammable fiber) are dispersed in water was prepared. The pulp serves to improve the capture rate of carbon fiber in paper-drafting. While the composition ration of the dispersion solution was carbon fiber: pulp=6:4 by weight, it is not particularly limited thereto, but may be of any value so long as it may be enough to catch carbon fibers in the shape like a sheet. The composition ratio of water is not limited to a specific value, but it may have any value so long as it may be enough to implement paper-drafting. The carbon fibers were a mixture of a pitch type carbon fibers (fiber length: average 3 mm, fiber diameter: average 15 μm) and PAN type carbon fibers (fiber length: average 3 mm, fiber diameter: average 7 μm).

The dispersion solution was screened through a sieve body for paper-drafting and was divided into water part and solid part. Thereby, a carbon sheet (carbon fiber aggregate) containing the carbon fibers of solid part and the pulp was obtained.

The carbon sheet was heated at a certain temperature for a certain time (380° C.×1 hr) in an atmosphere (containing oxygen). This burns out the pulp contained in the carbon sheet, thereby forming the carbon paper. The carbon paper is carbon fiber aggregate in which multiple carbon fibers become tangled with each other such that a plurality of micro pores is formed therebetween. The temperature and time during heat treatment are not limited to above values, but may have any values if they are enough to burn out the pulp. The grammage of the carbon paper was 4.0 mg/cm². Meanwhile, the grammage is not limited to the above value, but may vary properly.

(Growth of Carbon Nanotube)

The carbon paper was loaded in a reactor chamber of a sputtering apparatus and an aluminum substrate was formed on the carbon paper by means of a sputtering method (physical film-deposition method) using an aluminum source. The aluminum source used a pure aluminum target. Here, growth condition was set to the pressure of the reactor chamber of 0.6 Pa, the temperature of the substrate of room temperature (25° C.), and the thickness of the aluminum substrate of 20 nm. In addition, an iron thin film (an iron layer) was formed on the substrate by means of a sputtering method using an iron source. The iron source used a pure iron target. Here, the thickness of the iron thin film was set to 20 nm. The aluminum substrate and the iron thin film form a seed material that can serve as a catalyst to grow the carbon nanotubes. Meanwhile, the thicknesses of the substrate and the thin film were measured by an Auger Electron Spectroscopy (AES). The materials and/or thicknesses of the substrate and the thin film are considered to be important in forming groups of carbon nanotubes because they affect the catalyst operation. A catalyst for growth of carbon nanotubes was prepared by depositing the iron thin film (forming the thin film) and annealing at 350° C. for 5 minutes under a vacuumed condition of 100 Pa.

Next, the carbon nanotubes were grown using a Chemical Vapor Deposition (CVD) apparatus. The CVD process is a process by which source gas serving as a carbon source forming the carbon nanotubes is introduced into the reactor chamber with carrier gas, and the source gas is decomposed or reacted with respect to the surface of carbon fiber forming the carbon paper. In the CVD process, Ar gas was introduced as carrier gas into the reactor chamber that was already vacuumed to 10 Pa, and the pressure was regulated to have 4×10⁴ Pa. Next, the surface temperature of the carbon paper was elevated to 780° C., and the carbon paper was reacted for 6 minutes at that condition while volatilizing 5 cc liquid ethanol. Thereby, multiple carbon nanotubes (CNT) each having an extremely fine size were grown on the carbon fibers forming the carbon paper. Thus, the composite carbon according to this embodiment was formed.

According to the present embodiment, since the aluminum substrate and the iron thin film were formed on the carbon page, it was easy for the carbon nanotubes to be formed on the carbon fibers on the upper side of the carbon paper. However, it could be seen that the carbon nanotubes were also formed on the carbon fibers in the inside of the carbon paper in the thickness direction of the carbon paper.

In the composite carbon that was actually manufactured according to the present embodiment, multiple carbon nanotubes formed groups in which the lengthwise directions of the carbon nanotubes were aligned substantially perpendicular to the long axis of the fibrous carbon. The carbon nanotubes were made somewhat curled.

When measured using a scanning electron microscopy (SEM), the length of the carbon nanotube was 10-30 μm. When measured using a transmission electron microscopy (TEM), the diameter of the carbon nanotube was 10-30 nm. The amount of the loaded carbon nanotubes according to a weight difference before and after the CVD process was 0.3 mg/cm².

FIGS. 1 and 2 schematically show conceptual diagrams as seen in different direction with respect to the composite carbon manufactured by the above-mentioned method. As shown in FIGS. 1 and 2, it could be seen by an electron microscopy that the composite carbon has multiple carbon fibers (fibrous carbon) forming carbon paper and groups of multiple carbon nanotubes (CNT), each having the extremely fine size, grown on the surface of each carbon fiber.

Here, as can be understood from FIG. 1, when observing the composite carbon in the direction of the long axis (arrow direction X) of the carbon fiber, it was seen that groups of extremely fine multiple carbon nanotubes are arranged in high density in the long axis (arrow direction X) of the carbon fiber, into aggregate having the shape like a needle ice and in which the lengthwise directions of the carbon nanotubes are aligned in the same direction.

FIG. 2 shows the composite carbon seen in the different direction (an arrow direction XA in FIG. 1). As can be understood from FIG. 2, when observing the composite carbon from the end side direction of the long axis of the carbon fiber, it could be seen that the lengthwise directions of the carbon nanotubes (CNT) with respect to each carbon nanotube were aligned in the direction (arrow direction Y, the diametric direction of the carbon fiber) perpendicular to the long axis (arrow direction X) of the carbon fiber. In addition, the groups of the carbon nanotubes were formed into plural groups (four groups) at each 90° in the circumferential direction (arrow direction R shown in FIG. 2) of the carbon fiber, thereby forming spaces therebetween. It is supposed that such spaces contribute to improved porosity and gas-permeability.

That is, according to the shape shown in FIG. 2, the composite carbon was formed such that as viewed in a certain direction, multiple rows (four rows) of the group of the carbon nanotubes were formed with substantially regular intervals in the circumferential directions (arrow direction R) of the respective carbon fibers as if they formed multiple wings (four wings). The reason why the structure of the composite carbon has been obtained is not clear at present. The inventor supposes that the seed material formed of an iron thin film serving as a catalyst promotes directional growth of the carbon nanotubes while restricting disturbance of growth by the carbon fibers as the base material.

According to the present embodiment, the aluminum substrate is prepared on the carbon paper and then the iron catalyst is prepared on the aluminum substrate. Here, compared to the case where the iron catalyst is prepared on the carbon paper without preparing the aluminum substrate, the carbon nanotubes can be effectively formed as a group such that the lengthwise directions thereof are aligned in the same direction. Although not clear, it is supposed that forming the aluminum substrate makes the iron catalyst finer.

When observing the composite carbon, according to observation areas, the carbon nanotubes were also formed into two groups with an interval of 180° in the circumferential direction (arrow direction R) of the carbon fiber. Further, according to observation areas, the carbon nanotubes were also formed into three groups with an interval of 120° in the circumferential direction (arrow direction R) of the carbon fiber. Furthermore, according to observation areas, the carbon nanotubes were also formed into a single group.

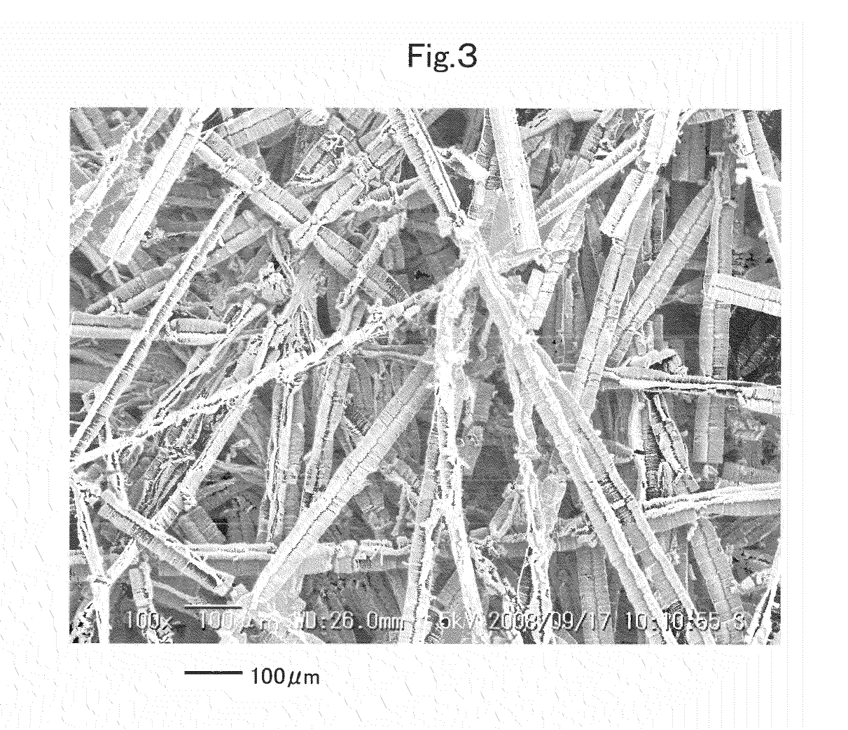

The scanning electron microscopic (SEM) photographs of the composite carbon taken in different sites are shown in FIGS. 3 to 6 together with a mark of unit length. As shown in FIGS. 3 to 6, it can be seen that carbon nanotubes, the length and diameter of which are smaller than those of the carbon fiber, are arranged in a group (in the form of needle ice) in the direction of the long axis of the carbon fiber. As shown in FIGS. 3 to 6, the multiple carbon nanotubes were arranged in the form of needle ice such that the lengthwise directions of the carbon nanotubes forming the group are aligned in the direction (the diametric direction of the carbon fiber) perpendicular to the long axis of the carbon fiber. FIG. 6 is an enlarged photograph showing a portion near the carbon nanotubes with a mark of unit length marked thereon.

The composite carbon manufactured according to the present embodiment can contribute to increased specific surface area and porosity. Further, since the carbon nanotubes are directly formed on the carbon fiber, the composite carbon can also contribute to reduced interfacial resistance, increased conductivity, and reduced electric resistance between the carbon nanotubes and the carbon fiber. Further, provided the composite carbon carries a catalyst such as platinum particles, an improvement in utilization of the catalyst can be expected. Meanwhile, while the carbon paper was CVD-processed with either side exposed to source gas, opposite sides of the carbon paper may be exposed to source gas, or otherwise the carbon paper may be CVD-processed while exposing one side and then the other side to the source gas.

According to the present embodiment, as set forth before, the iron thin film is formed on the aluminum substrate which is formed on the surface of the carbon fiber. When the aluminum substrate is formed on the surface of the carbon fiber, it is considered that the iron catalyst is made finer, which effectively forms the composite carbon having the structure according to the present invention.

### Second Embodiment

The second embodiment is basically implemented in the same manner as the first embodiment. According to the present embodiment, the carbon paper that is the same carbon paper as in the first embodiment was loaded in a reactor chamber of a sputtering apparatus while being placed on a substrate and an iron thin film was formed on the carbon paper by means of a sputtering method. Here, growth condition was set to the pressure of the reactor chamber of 0.6 Pa, the temperature of the substrate of room temperature (25° C.), the thickness of the substrate of 50 nm, and the thickness of the thin film of 65 nm.

According to the present embodiment, like the first embodiment, the composite carbon had multiple carbon fibers forming the carbon paper and groups of multiple carbon nanotubes which have the extremely fine size and which were grown on the surface of the respective carbon fibers in the form of needle ice (aligning pattern). The multiple carbon nanotubes were grown on the respective carbon fibers such that the lengthwise directions thereof are in the direction perpendicular to the long axis of the fibrous carbon.

### Third Embodiment

The third embodiment will now be described. It is considered that the composite carbon can be manufactured according to the manner of the present embodiment. The carbon paper can be manufactured by the same manner as in the first embodiment. An aluminum substrate of 20 nm thickness and an iron thin film of 20 nm thickness can be obtained on the carbon paper using a sputtering method. The iron thin film can form a seed material for growing the carbon nanotubes as a catalyst.

Next, the carbon nanotubes can be grown by means of a CVD apparatus under the condition that acetylene gas (hydrocarbon gas) is introduced at a flow rate of 200 cc/min (5-500 cc/min) as source gas, and nitrogen gas is introduced at a flow rate of 1000 cc/min (10-5000 cc/min) as carrier gas, so that the pressure is maintained under 10⁵ (10³˜10⁵)Pa. Here, in the gas flow rate, the reaction temperature (surface temperature of the carbon paper) may be selected as 700° C.-900° C., 770° C.-830° C., or 800° C. The reaction time may be considered to be for 1-60 minutes, or for 10 minutes.

### Fourth Embodiment

The fourth embodiment will now be described. It is considered that the composite carbon can be manufactured according to the manner of the present embodiment. The carbon paper can be manufactured by the same manner as in the first embodiment. An iron thin film is formed on the carbon paper by means of a dipping method. Here, a dipping solution is prepared in which powder type iron nitrate 9 hydrate is dissolved in a mixed solvent (composition ratio=8:2 by weight) of ethanol and terpineol with a concentration of 0.3 (0.001-1) mol/liter. The carbon paper is immersed in the dipping solution, is drawn out at a predetermined speed from the dipping solution, and finally is dried. The drawing speed may be 0.01-1.0 mm/sec, but it is not limited thereto. The drying temperature may be 200-350° C. or 250° C. Thereby, the iron thin film can be formed on the carbon paper.

### Fifth Embodiment

The fifth embodiment will now be described. First, as fibrous carbon, carbon paper (TGP-H-060 from Toray K. K., thickness 170p) was used. The carbon paper was not heat-treated as in the first embodiment. According to this carbon paper, good strength and conductivity can be expected. The carbon paper was loaded in a reactor chamber of a sputtering apparatus under substantially the same condition as in the first embodiment and an aluminum substrate (thinness: 7 nm) was formed on the carbon paper by means of a sputtering method. Here, growth condition was set to the pressure of the reactor chamber of 0.6 Pa and the temperature of the substrate of room temperature (25° C.). Next, an iron thin film (thickness: 5 nm) was formed on the substrate by means of a sputtering method. Thereby, a catalyst for growth of carbon nanotubes was prepared.

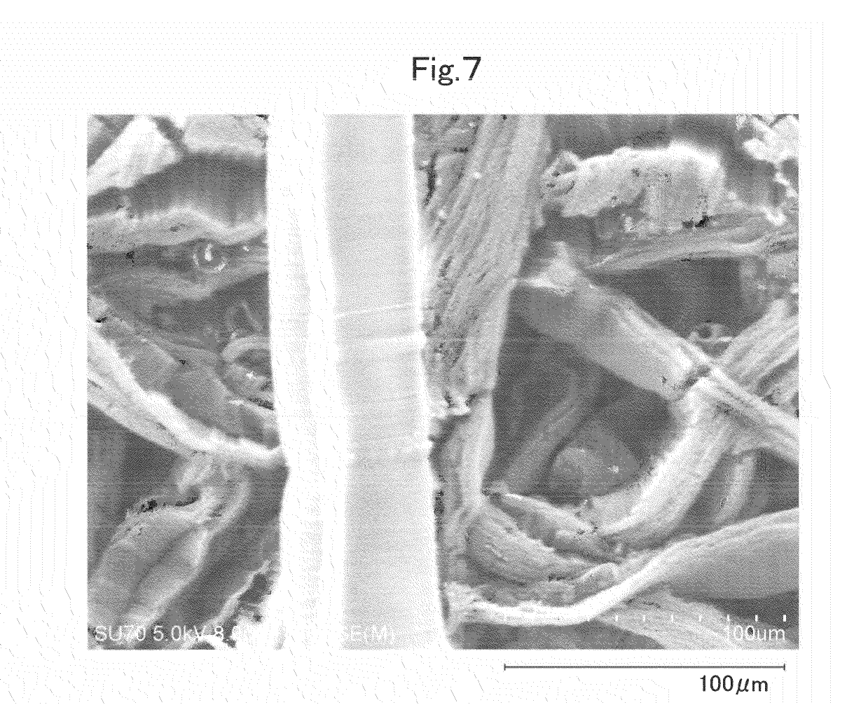

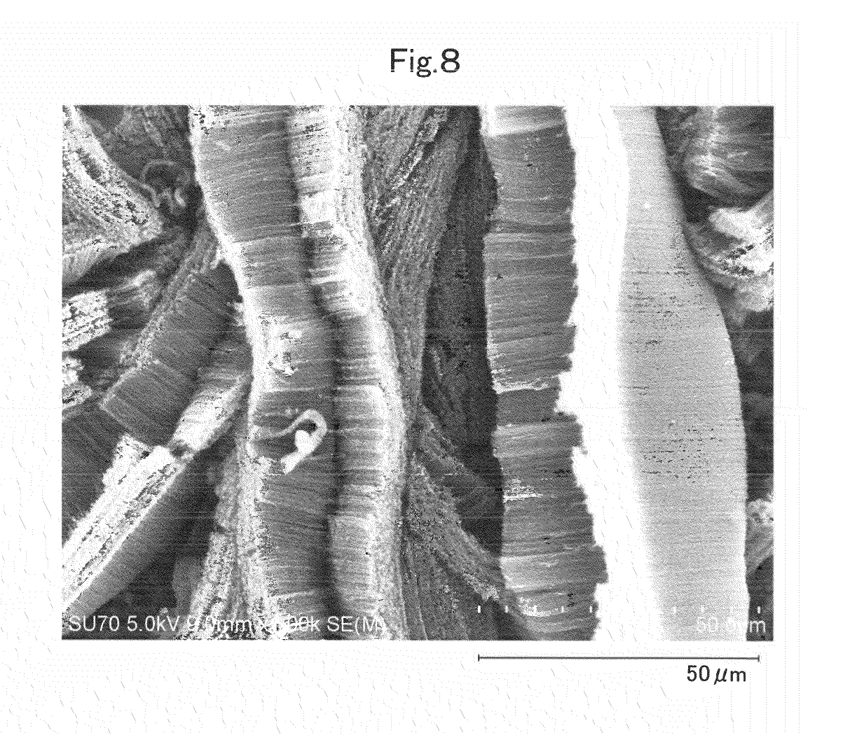

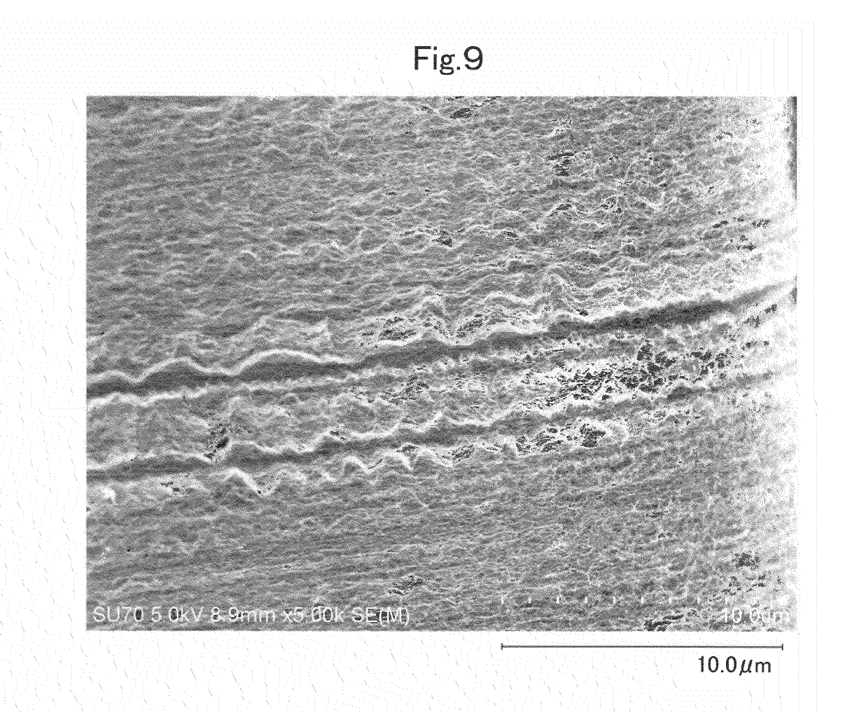

Next, the carbon nanotubes were grown using a Chemical Vapor Deposition (CVD) apparatus. Here, nitrogen gas was introduced as carrier gas into the reactor chamber that was already vacuumed to 10 Pa, and the pressure was regulated to have 0.1 MPa. Next, the substrate temperature was elevated to 620° C., and source gas (flow ratio=1:5) in which acetylene and nitrogen are mixed was supplied into the reactor chamber. In the source gas, a reaction was caused to occur for 6 minutes while the substrate temperature was elevated from 620° C. to 650° C. The flow rate of the source gas was set to 1000 cc/min. Thereby, multiple carbon nanotubes (CNT) each having an extremely fine size were grown on the carbon fibers forming the carbon paper. Thus, the composite carbon according to this embodiment was formed. FIGS. 7 to 9 are the scanning electron microscopic (SEM) photographs showing the structure of the composite carbon of this embodiment with a mark of unit length marked thereon. As shown in FIGS. 7 to 9, it can be seen that carbon nanotubes, the length and diameter of which are smaller than those of the carbon fiber, are arranged in a group (in the form of needle ice) in the direction of the long axis of the carbon fiber. As shown in FIGS. 7 to 9, the multiple carbon nanotubes were arranged such that the lengthwise directions of the carbon nanotubes forming the group are aligned in the direction perpendicular to the long axis of the carbon fiber. In addition, the carbon nanotubes were formed into multiple groups spaced a distance in the circumferential direction of the carbon fiber.

### Sixth Embodiment

The sixth embodiment will now be described. First, as fibrous carbon, carbon paper (TGP-H-060 from Toray K. K.) was used. The carbon paper was not heat-treated as in the first embodiment. The carbon paper was loaded in a reactor chamber of a sputtering apparatus under substantially the same condition as in the first embodiment and an aluminum substrate (thinness: 7 nm) was formed on the carbon paper by means of a sputtering method. Here, growth condition was set to the pressure of the reactor chamber of 0.6 Pa and the temperature of the substrate of room temperature (25° C.). Next, an iron thin film (thickness : 15 nm) was formed on the substrate by means of a sputtering method. Thereby, a catalyst for growth of carbon nanotubes was prepared.

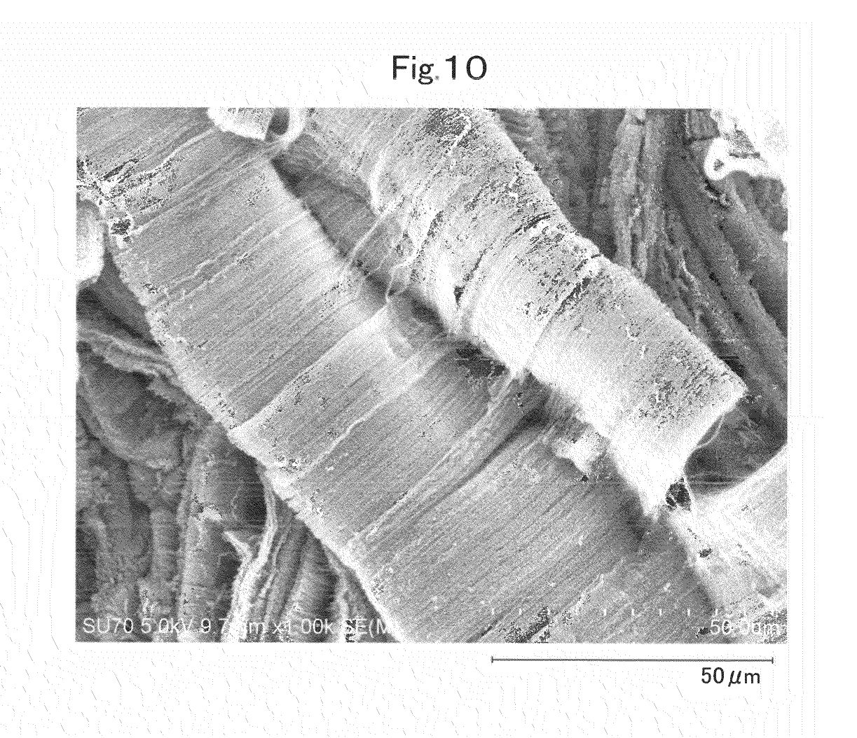

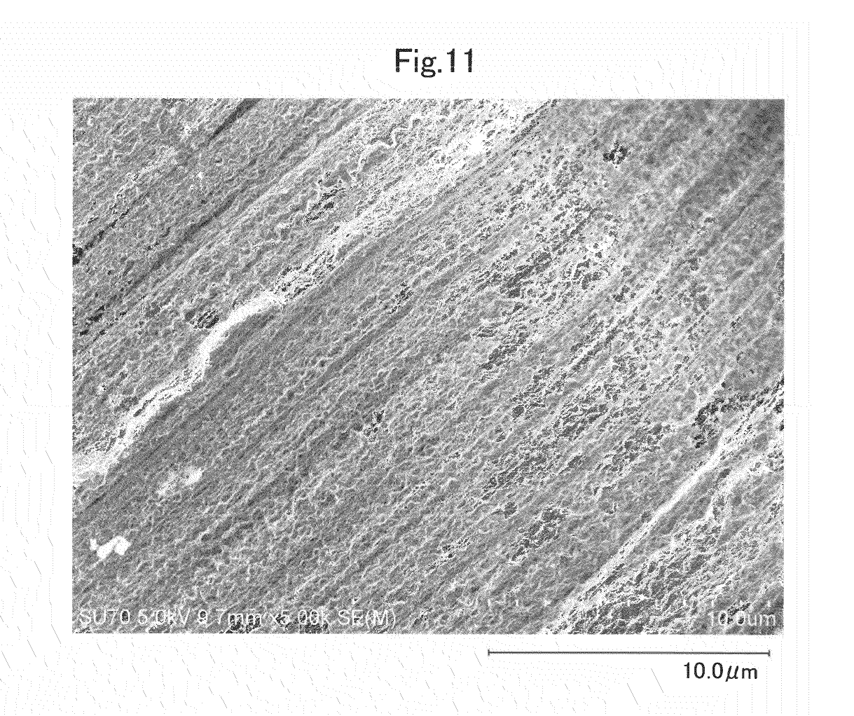

Next, the carbon nanotubes were grown on the carbon paper under the same condition as in the fifth embodiment, using the CVD apparatus. Thereby, multiple carbon nanotubes (CNT) each having an extremely fine size were grown on the carbon fibers forming the carbon paper. Thus, the composite carbon according to this embodiment was formed. FIGS. 10 and 11 are the scanning electron microscopic (SEM) photographs showing the structure of the composite carbon of this embodiment with a mark of unit length marked thereon. As shown in FIGS. 10 and 11, it can be seen that carbon nanotubes, the length and diameter of which are smaller than those of the carbon fiber, are arranged in a group (in the form of needle ice) in the direction of the long axis of the carbon fiber. As shown in FIG. 10, the multiple carbon nanotubes were arranged such that the lengthwise directions of the carbon nanotubes forming the group are aligned in the direction perpendicular to the long axis of the carbon fiber. In addition, as shown in FIG. 10, the carbon nanotubes were formed into multiple groups spaced a distance in the circumferential direction of the carbon fiber.

According to the present embodiment, since the aluminum substrate and the iron thin film were formed on the carbon page, it was easy for the carbon nanotubes to be formed on the carbon fibers on the upper side of the carbon paper. However, it could be seen that the carbon nanotubes were also formed on the carbon fibers in the inside of the carbon paper in the thickness direction of the carbon paper. In the composite carbon that was actually manufactured according to the present embodiment, multiple carbon nanotubes were formed into groups in which the lengthwise directions of the carbon nanotubes were aligned substantially perpendicular to the long axis of the fibrous carbon.

When measured using a scanning electron microscopy (SEM), the length of the carbon nanotube was 10-30 μm. When measured using a transmission electron microscopy (TEM), the diameter of the carbon nanotube was 10-30 nm. The amount of the loaded carbon nanotubes according to a weight difference before and after the CVD process was 0.3 mg/cm³.

### First Reference Example

The first reference example will now be described. First, as fibrous carbon, carbon paper (TGP-H-060 from Toray K. K.) was used. The carbon paper was not heat-treated as in the first embodiment. The carbon paper was loaded in a reactor chamber of a sputtering apparatus under substantially the same condition as in the first embodiment and an iron thin film (thinness: 15 nm) was formed on the carbon paper by means of a sputtering method. An aluminum substrate was not formed. Here, growth condition was set to the pressure of the reactor chamber of 0.6 Pa and the temperature of the substrate of room temperature (25° C.). Thereby, a catalyst for growth of carbon nanotubes was prepared. Next, the carbon nanotubes were grown on the carbon paper under the same condition as in the fifth embodiment, using the CVD apparatus. Thereby, multiple carbon nanotubes (CNT) each having an extremely fine size were grown on the carbon fibers forming the carbon paper. Thus, the composite carbon according to the first reference example was formed.

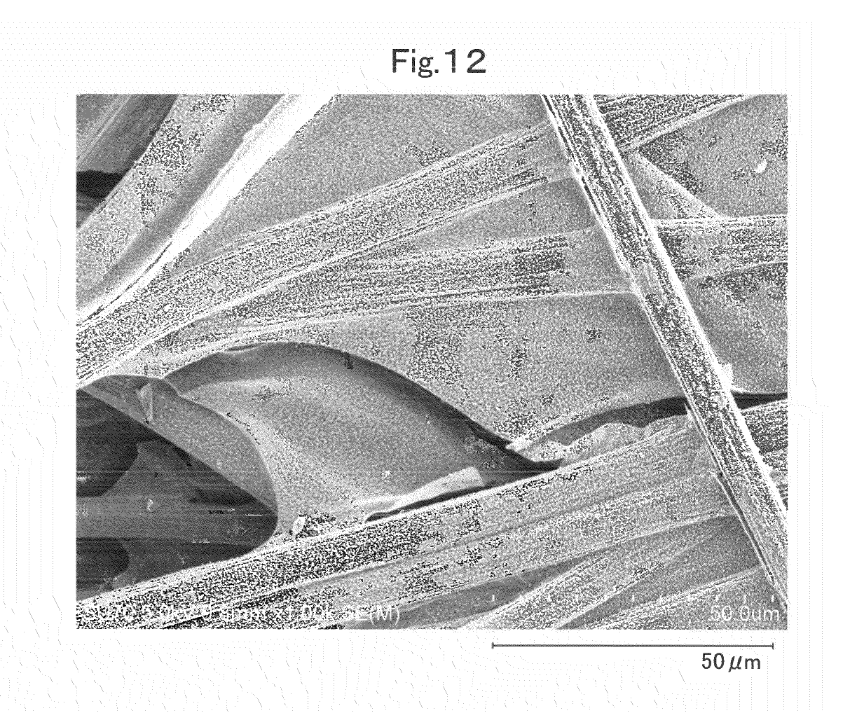

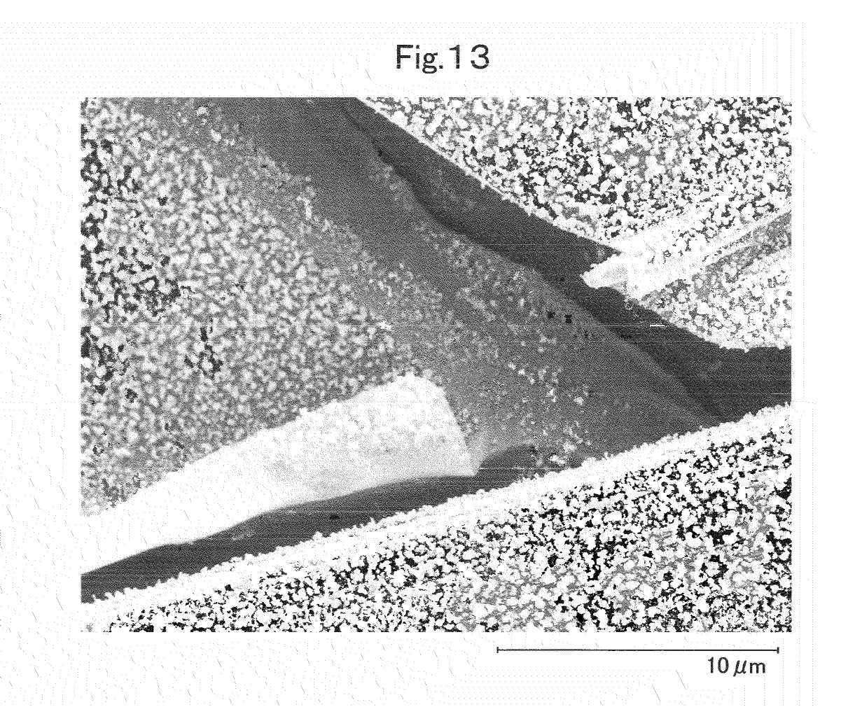

FIGS. 12 and 13 show the result of the first reference example. As shown in FIGS. 12 and 13, it can be seen that multiple carbon nanotubes having the extremely fine size were formed on the entire outer circumferential surface of the carbon fibers forming the carbon paper. However, the carbon nanotubes did not have the structure in which the lengthwise directions thereof are aligned in the same direction.

### First Application Example

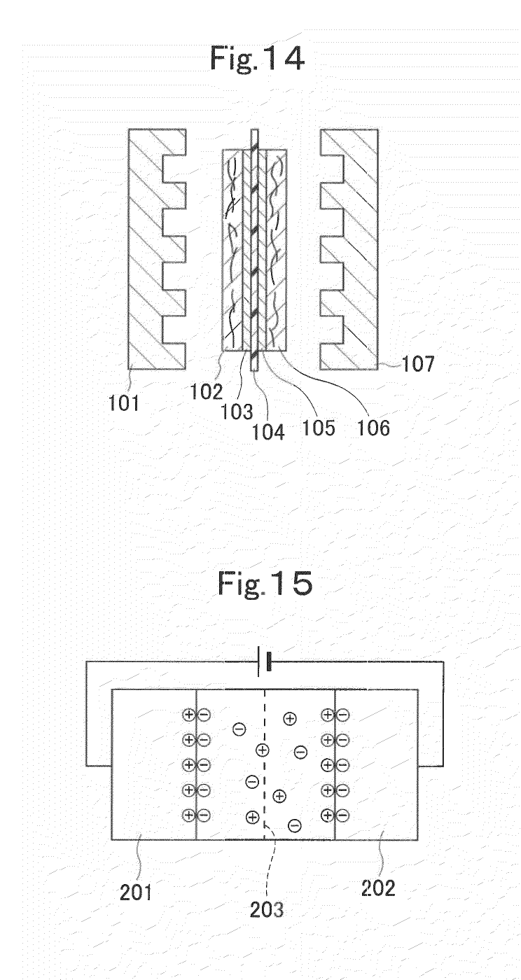

FIG. 14 schematically shows a cross-section of a major part of a sheet type fuel cell. The fuel cell includes a distributing plate 101 for an anode, a gas diffusion layer 102 for an anode, a catalyst layer 103 for an anode, an ion-conductive (proton-conductive) electrolyte membrane 104 made of fluorocarbon or hydrocarbon-based polymer, a catalyst layer 105 for a cathode, a gas diffusion layer 106 for a cathode, and a distributing plate 107 for a cathode, which are laminated in order in the thickness direction. The gas diffusion layers 102 and 106 have gas-permeability, so that reaction gas can pass through the diffusion layers. The electrolyte membrane 104 may be formed of an ion-conductive glass-based material, or otherwise may be formed by adding an acid (e.g. phosphoric acid) to polymer. Further, the present invention may also be adapted to a so called Phosphoric Acid Fuel Cell (PAFC) using phosphoric acid instead of an electrolyte membrane as an electrolyte.

The composite carbon of the present invention can be applicable to the gas diffusion layer 102 and/or 106. Here, since the composite carbon of the present invention has a large specific surface area and is porous, it can be expected that the composite carbon causes increased gas-permeability, restricted flooding, reduced electric resistance, and improved conductivity. The flooding means a phenomenon that a flow path of reaction gas is reduced due to water, so that gas-permeability becomes degraded.

In needed, the composite carbon of the present invention is also applicable to the catalyst layer 103 for an anode and/or the catalyst layer 105 for a cathode. Here, since the composite carbon of the present invention has a large specific surface area and is porous, it can be expected that the composite carbon performs an adjustment of discharge of produced water and of permeability of reaction gas, which is advantageous in restricting the flooding. Further, an improvement in utilization of catalyst particles such as platinum particles, ruthenium particles, platinum and ruthenium particles, or the like can be expected.

In addition, if needed, it is possible to integrate an electrode structure having both a function of a gas diffusion layer and a function of a catalyst layer by using the composite carbon. The integrated electrode in which platinum, ionomer, or water-repellent material, if needed, is added to the composite carbon is adapted to respective members, so that beside the above-mentioned effect, reduced interfacial resistance between the diffusion layer/catalyst layer and low-costs of electrode processing can be expected. Meanwhile, the fuel cell is not limited to the sheet type, but may be of a tube type.

### Second Application Example

FIG. 15 schematically shows a capacitor for current collection. The capacitor includes a porous positive electrode 201 made of carbon-based material, a porous negative electrode 202 made of carbon-based material, and a separator 203 separating the positive electrode 201 and the negative electrode 202 from each other. Since the composite carbon of the present invention has a large specific surface area and is porous, if it is used with the positive electrode 201 and/or the negative electrode 202, increased capacitance can be expected and capability of the capacitor can be improved.

### Other Embodiment

While the first embodiment has adapted carbon paper formed through paper-drafting, the present invention is not limited thereto, but may adapt carbon paper that is formed by a method other than paper-drafting, or carbon cloth or carbon felt made of fabric. While the first embodiment has adapted carbon fibers, forming the carbon paper, in which pitch-based carbon fibers sourced from tar pitch or petroleum pitch and PAN-based carbon fibers sourced from acryl fibers are mixed, the carbon fibers may consist of only pitch-based carbon fibers or only PAN-based carbon fibers. Instead of carbon fiber, carbon nanofiber or vapor-grown carbon fiber may also be adapted. Meanwhile, the fibrous carbon may not be aggregate, but may be dispersion type fibrous carbon.

A material serving as a catalyst includes for example transition metal such as cobalt, nickel, or the like, beside iron, and an alloy thereof. In order to improve wettability of the catalyst thin film in the circumferential direction of the carbon fiber and in the depth direction of the fibrous carbon, it is effective that a substrate or a target is turned in the sputtering process, and that the dipping method shown in the fourth embodiment is also performed. In addition, on the contrary, it is also possible to degrade the wettability of the catalyst thin film so as to locally form the carbon nanotubes, or to make the produced carbon nanotubes (CNT) inclined against inside or depth direction. As CVD pre-treatment, an annealing process may be adapted for alloying or oxidizing the catalyst metal. The annealing may has a temperature range of e.g. 300-900° C. The reaction temperature (specifically the surface temperature of the carbon paper) in the CVD process may have a range of e.g. 100-700° C. Beside the above, the present invention is not limited to the above-mentioned embodiments, but may vary properly without departing from spirit of the invention.

### INDUSTRIAL APPLICABILITY

The present invention is applicable to carbon material that requires for a large specific surface area. For example, the present invention can be used with carbon material used for a fuel cell, carbon material used for a variety of cells such as a capacitor, a secondary cell, a liquid junction solar cell, or the like, carbon material used for a water-purifying filter, carbon material used for gas adsorption, or the like.

1. A composite carbon, comprising:
a fibrous carbon extending in a direction of a long axis thereof of the fibrous carbon; and
multiple carbon nanotubes formed on the fibrous carbon and having a smaller diameter than a diameter of the fibrous carbon,
wherein the carbon nanotubes are formed as a group of multiple carbon nanotubes with a lengthwise direction thereof of the multiple carbon nanotubes aligned in the same direction.

2. The composite carbon of claim 1, wherein the group of the carbon nanotubes comprise a plurality of groups spaced apart a distance in a circumferential direction of the fibrous carbon.

3. The composite carbon of claim 1, wherein the group of the carbon nanotubes comprises one to four groups in a circumferential direction of carbon fiber.

4. The composite carbon claim 1, wherein the multiple carbon nanotubes form a group of the carbon nanotubes aligned in the long axis of the fibrous carbon.

5. The composite carbon of claim 1, wherein the lengthwise direction of the carbon nanotube is perpendicular to the long axis of the fibrous carbon.

6. The composite carbon of claim 1, wherein the fibrous carbon is carbon fiber forming a carbon fiber aggregate comprising a plurality of carbon fibers.

7. The composite carbon of claim 6, wherein the carbon fiber aggregate is at least one selected from the group consisting of carbon paper, carbon cloth, and carbon felt.

8. The composite carbon of claim 7, wherein the carbon fiber aggregate is the carbon paper and is formed by:
screening a dispersion solution comprising the carbon fiber and cellulose-comprising flammable fiber though a sieve screen for paper-drafting, thereby forming a carbon fiber pulp aggregate; and
burning the cellulose-comprising fiber, thereby forming the carbon paper.

9. The composite carbon of claim 1, wherein the carbon nanotubes are formed on an iron thin film formed on the surface of the fibrous carbon.

10. The composite carbon of claim 9, wherein the iron thin film is formed on an aluminum substrate formed on the surface of the fibrous carbon.

11. The composite carbon of claim 10, wherein the aluminum substrate has a thickness of 2-50 nm, and the iron thin film has a thickness of 2-65 nm.

12. A method of manufacturing a composite carbon comprising:
preparing a fibrous carbon extending in a direction of a long axis of the fibrous carbon and having an aluminum substrate thereon and an iron catalyst stuck on the aluminum substrate; and
forming, on a surface of the fibrous carbon, multiple carbon nanotubes having a smaller diameter than a diameter of the fibrous carbon, as a group of carbon nanotubes with the lengthwise directions of the carbon nanotubes aligned in the same direction, by CVD-processing a carbon source with a CVD apparatus.

13. The method of claim 12, wherein the aluminum substrate has a thickness of 2-50 nm, and the iron catalyst has a thickness of 2-65 nm.

14. The composite carbon of claim 2, wherein the group of the carbon nanotubes comprises one to four groups in a circumferential direction of carbon fiber.

15. The composite carbon of claim 2, wherein the multiple carbon nanotubes form a group of the carbon nanotubes aligned in the long axis of the fibrous carbon.

16. The composite carbon of claim 3, wherein the multiple carbon nanotubes form a group of the carbon nanotubes aligned in the long axis of the fibrous carbon.

17. The composite carbon of claim 2, wherein the lengthwise direction of the carbon nanotube is perpendicular to the long axis of the fibrous carbon.

18. The composite carbon of claim 3, wherein the lengthwise direction of the carbon nanotube is perpendicular to the long axis of the fibrous carbon.

19. The composite carbon of claim 2, wherein the fibrous carbon is carbon fiber forming a carbon fiber aggregate comprising a plurality of carbon fibers.

20. The composite carbon of claim 3, wherein the fibrous carbon is carbon fiber forming a carbon fiber aggregate comprising a plurality of carbon fibers.
